(19) United States
(12) Patent Application Publication
(10) Pub. No.: US 2026/0245993 A1
(43) Pub. Date: Aug. 20, 2026

(54) BATTERY MANAGEMENT SYSTEM AND CONTROL METHOD THEREOF

(71) Applicant: Samsung Electronics Co., Ltd., Suwon-si (KR)

(72) Inventors: Youngchul KANG, Suwon-si (KR); Jui LEE, Suwon-si (KR); Jungjae LEE, Suwon-si (KR)

(21) Appl. No.: 19/643,430

(22) Filed: Apr. 9, 2026

Related U.S. Application Data
(63) Continuation of application No. PCT/KR2024/014771, filed on Sep. 27, 2024.

(30) Foreign Application Priority Data
Oct. 12, 2023 (KR) 10-2023-0136210

(51) Int. Cl. H01M 10/42; H01M 50/204; H01M 50/247; H01M 50/503; H01M 50/583

(52) U.S. Cl. CPC H01M 10/425; H01M 50/204; H01M 50/247; H01M 50/503; H01M 50/583; H01M 2010/4271; H01M 2200/103; H01M 2220/30

(57) ABSTRACT

A battery management system may include: a first battery cell; a second battery cell; a cable connecting the first battery cell and the second battery cell to each other; and a battery management circuit which monitors the voltage of the first battery cell and the second battery cell and determines whether to switch states of the first battery cell and the second battery cell to a permanent fail state on the basis of the voltage of the first battery cell and the second battery cell and whether the first battery cell and the second battery cell are connected by the cable.

### CROSS-REFERENCE TO RELATED APPLICATIONS

This application is a continuation application of International Application No. PCT/KR2024/079906, filed on Sept. 27, 2024, in the Korean Intellectual Property Receiving Office, and claiming priority to KR Application No. 10-2023-013620 filed Oct. 12, 2023, the disclosures of which are all hereby incorporated by reference herein in their entireties.

### TECHNICAL FIELD

Certain example embodiments may relate to a battery management system, a control method of a battery management system, and/or a wearable device including a battery management system.

### BACKGROUND ART

In general, a walking assistance device may refer to a machine and/or device used for exercise, and/or a machine or device that helps patients, unable to walk on their own because of diseases, accidents, or other causes with their walking exercises for rehabilitation treatment. In a rapidly aging society, a growing number of people have experienced difficulty exercising normally or inconvenience in exercising, and there is an increasing interest in the walking assistance device. The walking assistance device may be worn on a body of a user to assist the user in walking by providing the necessary muscular strength and to induce the user to walk in a normal walking pattern. The walking assistance device may assist the user in performing one or more of various leg exercises (e.g., power walking, jogging, stair climbing, lunge, and/or stretching). The walking assistance device may include a chargeable battery for portable use.

### SUMMARY

A battery management system according to an example embodiment may include a first battery cell, a second battery cell, a cable that connects, directly or indirectly, the first battery cell and the second battery cell to each other, and a battery cell circuit configured to monitor respective voltages of the first battery cell and the second battery cell and determine whether to switch states of the first battery cell and the second battery cell to a permanent fail state, based on the respective voltages of the first battery cell and the second battery cell and whether the first battery cell and the second battery cell are connected, directly or indirectly, via the cable. “Based on” as used herein covers based at least on.

A method of controlling a battery management system including battery cells, a cable connecting, directly or indirectly, the battery cells, and a battery management circuit, may include monitoring respective voltages of the battery cells, when an abnormal voltage of at least one of the battery cells is detected, determining whether the battery cells are connected, directly or indirectly, via the cable, when the battery cells are detected not to be connected by the cable, switching states of the battery cells to a standby state without switching to a permanent fail state, and when the battery cells are detected to be connected by the cable in the standby state, switching the states of the battery cells to a normal operation state.

### BRIEF DESCRIPTION OF DRAWINGS

The above and other aspects, features, and advantages of certain embodiments of the present disclosure will be more apparent from the following detailed description, taken in conjunction with the accompanying drawings.

FIG. 1 is a diagram illustrating an overview of a wearable device worn on a body of a user according to an example embodiment.

FIG. 2 is a diagram illustrating an exercise assistance system according to an example embodiment.

FIG. 3 illustrates a rear schematic view of a wearable device according to an example embodiment.

FIG. 4 illustrates a left side view of a wearable device according to an example embodiment.

FIGS. 5A and 5B are diagrams illustrating configurations of a wearable device according to an example embodiment.

FIG. 6 is a diagram illustrating an interaction between a wearable device and an electronic device according to an example embodiment.

FIG. 7 is a diagram illustrating a configuration of a battery management system according to an example embodiment.

FIG. 8 is a diagram illustrating a battery management circuit and a battery cell circuit according to an example embodiment.

FIG. 9 is a flowchart of operations of a control method of a battery management system according to an example embodiment.

FIG. 10 is a diagram illustrating a battery management system including a flexible printed circuit board (FPCB) according to an example embodiment.

FIGS. 11A and 11B are diagrams illustrating implementation examples in which a battery management system is provided in a wearable device according to an example embodiment.

### DETAILED DESCRIPTION

The following detailed structural or functional description is provided as an example only and various alterations and modifications may be made to the embodiments. Accordingly, the embodiments are not construed as limited to the disclosure and should be understood to include all changes, equivalents, and replacements within the idea and the technical scope of the disclosure.

As used herein, the singular form is intended to include the plural forms as well, unless the context clearly indicates otherwise. It will be further understood that the terms "comprises/comprising" and/or "includes/including" when used herein, specify the presence of stated features, integers, steps, operations, elements, and/or components, but do not preclude the presence or addition of one or more other features, integers, steps, operations, elements, components and/or groups thereof.

Unless otherwise defined, all terms, including technical and scientific terms, used herein have the same meaning as commonly understood by one of ordinary skill in the art to which the present disclosure pertains. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. When describing the embodiments with reference to the accompanying drawings, like reference numerals refer to like components, and any repeated description related thereto will be omitted.

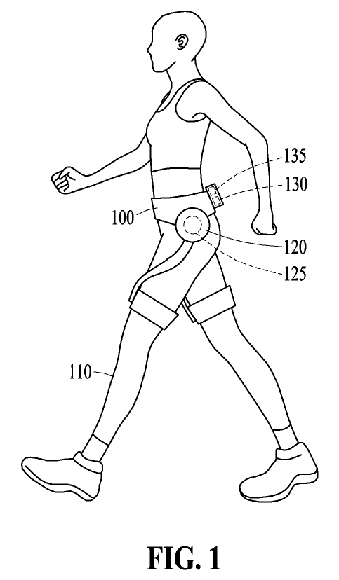

FIG. 1 is a diagram illustrating an overview of a wearable device worn on a body of a user according to an embodiment.

Referring to FIG. 1, a wearable device 100 in an embodiment may be a device worn on a body of a user 110 to assist the user 110 in walking, exercising, and/or working. The wearable device 100 may be used to measure a physical ability (e.g., a walking ability, an exercise ability, and an exercise posture) of the user 110. The term "wearable device" may be replaced with "'wearable robot'", "walking assistance device", or "exercise assistance device". The user 110 may be a person who wears the wearable device 100 and walks or exercises.

The wearable device 100 may be worn on a body (e.g., a lower body (legs, ankles, knees, etc.) or an upper body (a torso, a waist, arms, wrists, etc.)) of the user 110 to apply an external force, such as an assistance force and/or a resistance force, to a body motion of the user 110. The assistance force may be a force applied in the same direction as a direction of a body motion of the user 110 and may refer to a force assisting the body motion of the user 110. The resistance force may be a force applied in an opposite direction of the direction of the body motion of the user 110 and may refer to a force hindering the body motion of the user 110. The term "resistance force" may be also referred to as an "exercise load".

In an embodiment, the wearable device 100 may operate in a walking assistance mode for assisting the user 110 in walking. In the walking assistance mode, the wearable device 100 may assist the user 110 in walking by applying an assistance force generated by a driving module 120 of the wearable device 100 to the body of the user 110. The wearable device 100 may enable the user 110 to walk independently or to walk for a long time by providing a force required for the user 110 to walk, thereby extending the walking ability of the user 110. The wearable device 100 may help in improving an abnormal walking habit or walking posture of a walker.

In an embodiment, the wearable device 100 may operate in an exercise assistance mode to enhance an exercise effect of the user 110 or provide various exercise experiences to the user 110. The exercise assistance mode may include a resistance mode and an assistance mode. The resistance mode may refer to a mode that hinders a body motion of the user 110 or provides resistance to the body motion of the user 110 by applying a resistance force generated by a driving module 120 to the body of the user 110. When the wearable device 100 is a hip-type wearable device worn on the waist (or pelvis) and legs (e.g., thighs) of the user 110, in the resistance mode, the wearable device 100 may further enhance the exercise effect on the legs of the user 110 by providing an exercise load to a leg motion of the user 110 while the wearable device 100 is worn on the legs. The assistance mode may refer to a mode to apply an assistance force for assisting the body motion of the user 110 to the body of the user 110. In the assistance mode, the assistance force, which is a force in the same direction as the body motion, may be provided to the user 110. For example, when a person with a disability or an elderly person wears the wearable device 100 and exercises, the wearable device 100 may provide the assistance force to assist the body motion. In the assistance mode, the wearable device 100 may provide a force in the same direction as the direction of the leg motion of the user 110, and the user 110 may perform exercise with a small force. In an exercise program performed using the wearable device 100, a combination of the resistance mode and the assistance mode may be operated. For example, the wearable device 100 may provide an assistance force and a resistance force in combination for each exercise session or time interval, for example, providing an assistance force in an exercise session and a resistance force in another exercise session. In the exercise assistance mode, various exercise programs may be operated depending on the exercise purpose and/or physical ability of the user 110. The exercise program may be exercising content performed by the user 110 using the wearable device 100 and may include, for example, a cardio exercise, strength training, posture balancing, or any combination thereof. The types of exercise programs are not limited thereto and may vary. According to the exercise program performed by the wearable device 100, the resistance mode and the assistance mode may be alternatively activated appropriately depending on the exercise program performed by the wearable device 100, and a target exercise speed that is suitable for an appropriate physical condition (e.g., a heart rate) of the user 110 may be guided to the user while the user 110 performs the exercise.

In an embodiment, the wearable device 100 may operate in a physical ability measurement mode to measure the physical ability of the user 110. The wearable device 100 may measure motion information of the user 110 using a sensor (e.g., an angle sensor 125 or an inertial measurement unit (IMU) 135) provided in the wearable device 100 while the user 110 walks and/or performs exercise and may evaluate the physical ability of the user 110 based on the measured motion information. For example, a gait index (e.g., a step count, a total walking distance, or a step length) or an exercise ability indicator (e.g., muscular strength, endurance, balance, or exercise motion) of the user 110 may be estimated through the motion information of the user 110 measured by the wearable device 100.

In some embodiments, the description is provided based on an example in which the wearable device 100 is a hip-type wearable device as illustrated in FIG. 1, but the embodiments are not limited thereto. As described above, the wearable device 100 may be worn on another body part (e.g., upper arms, lower arms, hands, calves, and feet) other than the waist and legs (particularly, the thighs). The shape and configuration of the wearable device 100 may vary depending on the body part on which the wearable device 100 is worn.

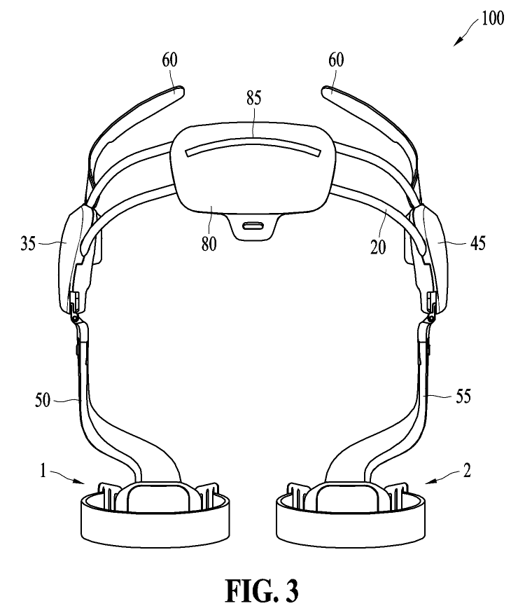

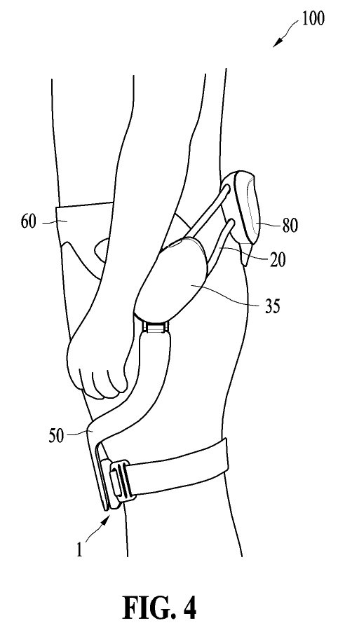

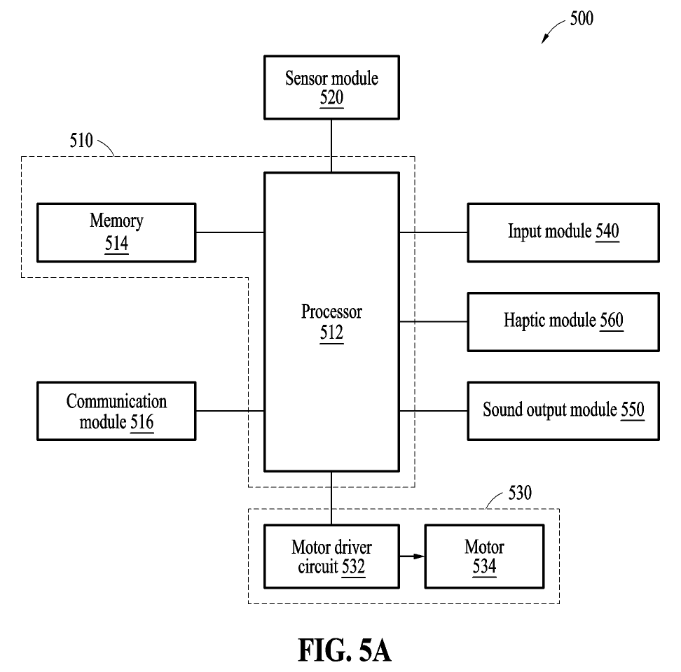

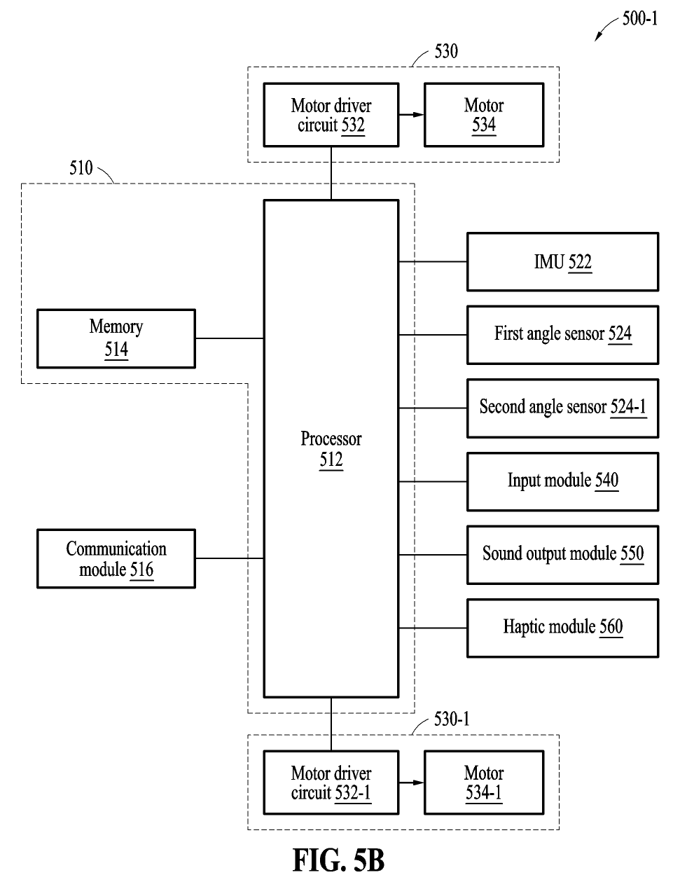

The wearable device 100 may include a support frame (e.g., a waist support frame 20 illustrated in FIGS. 3 and 4) to support the body of the user 110 when the wearable device 100 is worn on the body of the user 110, the driving module 120 (e.g., driving modules 35 and 45 of FIG. 3) to generate a torque applied to the legs of the user 110, a torque transmission frame (e.g., a first torque transmission frame 55 and a second torque transmission frame 50 of FIG. 3) to transmit a torque generated by the driving module 120 to the legs of the user 110, a sensor module (e.g., a sensor module 520 of FIG. 5A) including one or more sensors to obtain sensor data including motion information about a body motion (e.g., a leg motion or an upper body motion) of the user 110, and a control module 130 (e.g., a control module 510 of FIGS. 5A and 5B) to control operations of the wearable device 100.

In an embodiment, the wearable device 100 may include the angle sensor 125 and the IMU 135. The angle sensor 125 may measure a rotation angle of the torque transmission frame of the wearable device 100 corresponding to a hip joint angle of the user 110. The angle sensor 125 may include, for example, an encoder and/or a hall sensor. In an embodiment, the angle sensor 125 may be disposed near a position where a motor included in the driving module 120 is connected, directly or indirectly, to the torque transmission frame. The IMU 135 may include an acceleration sensor and/or an angular velocity sensor, and may measure a change in acceleration and/or angular velocity according to a motion of the user 110. The IMU 135 may measure, for example, a motion value of a waist support frame (e.g., the lumber support frame 20 of FIG. 3) or a base body (e.g., a base body 80 of FIG. 3) of the wearable device 100. The motion value of the waist support frame or the base body measured by the IMU 135 may correspond to a waist motion value (or an upper body motion value) of the user 110.

In an embodiment, the control module 130 and the IMU 135 may be disposed in the base body (e.g., the base body 80 of FIG. 3) of the wearable device 100. The base body may be positioned on the waist of the user 110 while the user 110 wears the wearable device 100. The base body may be formed on or attached to the outside of the waist support frame of the wearable device 100. The base body may support a lumbar region of the user 110.

In an embodiment, the wearable device 100 may provide haptic feedback to the user via a haptic module (e.g., a haptic module 560 of FIGS. 5A and 5B). The haptic module may include one or more haptic actuators providing haptic feedback.

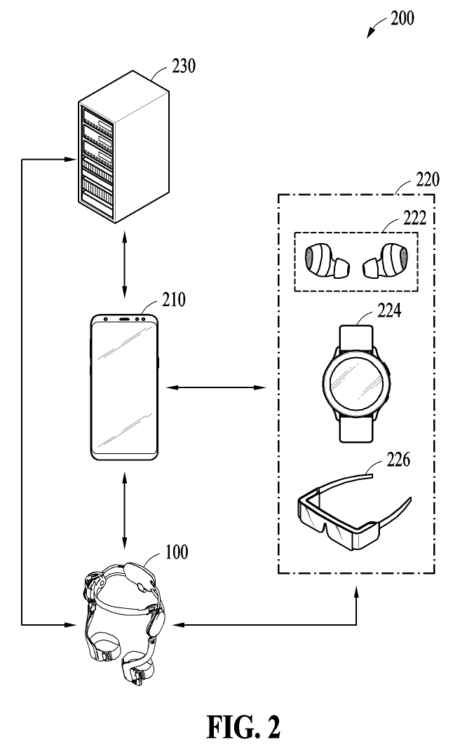

FIG. 2 is a diagram illustrating an exercise assistance system according to an embodiment.

Referring to FIG. 2, an exercise assistance system 200 may include the wearable device 100, an electronic device (or a user terminal) 210, another wearable device 220, and a server 230. At least one of the devices (e.g., the electronic device 210, the other wearable device 220, and the server 230) other than the wearable device 100 may be omitted from the exercise assistance system 200, or one or more other devices (e.g., a dedicated controller device for the wearable device 100) may be added to the exercise assistance system 200.

In an embodiment, in the walking assistance mode, the wearable device 100 may be worn on the body of the user to assist a motion of the user. For example, the wearable device 100 may be worn on the legs of the user and may assist the user in walking by generating the assistance force to assist a leg motion of the user.

In an embodiment, in the exercise assistance mode, the wearable device 100 may generate a resistance force for hindering a body motion of the user and/or an assistance force for assisting the body motion of the user and may apply the generated resistance force and/or the generated assistance force to the body of the user to enhance the exercise effect of the user. In the exercise assistance mode, via the electronic device 210, the user may select an exercise program (e.g., a cardio exercise such as power walking or outside walking, strength training such as squat, split lunge, dumbbell squat, and lunge and knee up, stretching, a posture balancing exercise, or any combination thereof) that the user desires to perform using the wearable device 100 and/or exercise intensity applied to the exercise program. The wearable device 100 may control the driving module of the wearable device 100 according to the exercise program selected by the user. The wearable device 100 may adjust the magnitude of the resistance force and/or the assistance force applied to the user according to the exercise intensity selected by the user. For example, the wearable device 100 may control the driving module to generate a resistance force corresponding to the exercise intensity selected by the user. As the exercise intensity increases, the magnitude of the resistance force applied to the user may increase.

The wearable device 100 may transmit sensor data measured via the sensor (e.g., the angle sensor or the IMU) to the electronic device 210 and may receive a control signal related to operations of the wearable device 100 from the electronic device 210. The wearable device 100 may provide (or output) feedback (e.g., visual feedback, auditory feedback, or haptic feedback) corresponding to a state of the wearable device 100 according to the control signal received from the electronic device 210. For example, the wearable device 100 may provide visual feedback via a lighting unit (e.g., a lighting unit 85 of FIG. 3) and may provide auditory feedback via a sound output module (e.g., a sound output module 550 of FIGS. 5A and 5B).

The electronic device 210 may communicate with the wearable device 100 via wireless communication, may remotely control the wearable device 100, or may provide the user with state information about a state (e.g., a booting state, a charging state, a sensing state, or an error state) of the wearable device 100. The electronic device 210 may recommend an exercise program using the wearable device 100 to the user and may analyze the exercise performed by the user. The electronic device 210 may receive, from the wearable device 100, sensor data obtained by the sensor of the wearable device 100 and may estimate a current exercise state, an exercise result, an exercise posture, and/or the physical ability of the user based on the received sensor data. The electronic device 210 may provide the user with the estimated current exercise state, the estimated exercise result, the estimated exercise posture, and/or the estimated physical ability of the user via a graphical user interface (GUI).

In an embodiment, the user may execute a program (e.g., an application) in the electronic device 210 to control the wearable device 100 and may control the operation or a setting value (e.g., the magnitude of torque output from the motor of the driving module, the volume level of audio output from the sound output module, and brightness of the lighting unit) of the wearable device 100 via the program. The program executed by the electronic device 210 may provide a GUI for interaction with the user. The electronic device 210 may be various types of devices. For example, the electronic device 210 may include, for example, a portable communication device (e.g., a smartphone), a computer device, a portable multimedia device, or home appliance (e.g., a television, an audio device, and a projector device), but is not limited thereto.

According to an embodiment, the electronic device 210 may be connected to the server 230 using short-range wireless communication or cellular communication. The server 230 may receive user profile information of the user of the wearable device 100 from the electronic device 210 and may store and manage the received user profile information. For example, the user profile information may include information about at least one of a name, age, gender, height, weight, medical history, or a body mass index (BMI). The server 230 may receive exercise history information about an exercise performed by the user from the electronic device 210 and may store and manage the received exercise history information. The server 230 may provide the electronic device 210 with various exercise programs or physical ability measurement programs to be provided to the user. In an embodiment, the server 230 may be connected, directly or indirectly, to the wearable device 100. The server 230 may receive sensor data measured by the wearable device 110 from the wearable device 100 and may transmit a control signal to control the operation of the wearable device 100 and/or data related to the exercise program to the wearable device 100. In an embodiment, the server 230 may be a cloud server.

According to an embodiment, the wearable device 100 and/or the electronic device 210 may be connected to the other wearable device 220. The exercise result information, physical ability information, and/or exercise motion evaluation information of the user that are determined by the electronic device 210 may be transmitted to the other wearable device 220 and may be provided to the user via the other wearable device 220. The state information of the wearable device 100 may be transmitted to the other wearable device 220 and may be provided to the user via the other wearable device 220. In an embodiment, the wearable device 100, the electronic device 210, and the other wearable device 220 may be connected to each other via wireless communication (e.g., Bluetooth communication or wireless fidelity (Wi-Fi) communication). The other wearable device 220 may be, for example, wireless earphones 222, a smartwatch (or a watch-type wearable device) 224, or smartglasses (a glasses or goggle-type wearable device) 226, but is not limited thereto.

In an embodiment, the wireless earphones 222 may be wirelessly connected to the electronic device 210 and/or the wearable device 100 to output a guide voice, music, and/or a sound effect related to the exercise program. The wireless earphones 222 may provide information (e.g., introduction to the exercise program or remaining time) related to the exercise program to the user or ask the user to select via the guide voice. The wireless earphones 222 may include a microphone, and the microphone may receive a voice input of the user. The voice input received via the microphone may be transmitted to the electronic device 210, and voice recognition for the voice input may be performed in the electronic device 210.

In an embodiment, the smartwatch 224 may include a biometric sensor (e.g., a heart rate sensor or an electromyograph sensor) for measuring a biosignal including heart rate information of the user and may transmit the biosignal measured by the biometric sensor to the electronic device 210 and/or the wearable device 100. The electronic device 210 may estimate electromyograph information and/or the heart rate information (e.g., a current heart rate, a maximum heart rate, and an average heart rate) of the user based on the biosignal received from the smartwatch 224 and may provide the estimated electromyograph information and/or the estimated heart rate information to the user. The heart rate information and/or the electromyograph information may be used to determine haptic intensity of haptic feedback provided via the wearable device 100.

In an embodiment, the smartwatch 224 may include an IMU for measuring motion information of the user and/or a position sensor for measuring position information of the user and may transmit the motion information and/or the position information of the user to the electronic device 210 and/or the wearable device 100. The smartwatch 224 may include a communication module (e.g., a short-range communication module) for communicating with other devices (e.g., the electronic device 210 or the wearable device 100). In an embodiment, the smartwatch 224 may provide an interface related to the exercise program via a display. The interface related to the exercise program may be implemented by a separate application installed in the smartwatch 224. The user may also control the wearable device 100 via the smartwatch 224.

In an embodiment, the smart glasses 226 may provide information to the user via a glasses-type display. For example, the smart glasses 226 may output, via the display, information, such as a current exercise speed, an amount of exercise currently achieved, a duration of exercise, and biometric information in an exercise mode. In addition, the smart glasses 226 may output a screen to guide the user on an exercise path.

FIG. 3 illustrates a rear schematic view of a wearable device according to an embodiment. FIG. 4 illustrates a left side view of a wearable device according to an embodiment.

Referring to FIGS. 3 and 4, the wearable device 100 according to an embodiment may include the base body 80, the waist support frame 20, the driving modules 35 and 45, the torque transmission frames 50 and 55, thigh fastening portions 1 and 2, and a waist fastening portion 60. The base body 80 may include the lighting unit 85. In an embodiment, at least one (e.g., the lighting unit 85) of the components may be omitted from the wearable device 100, or one or more other components may be added to the wearable device 100.

The base body 80 may be positioned on the lumbar region of the user while the user is wearing the wearable device 100. The base body 80 may be mounted on the lumbar region of the user to provide a cushioning feeling to the waist of the user and may support the waist of the user. The base body 80 may be hung on a hip region (an area of the hips) to prevent or reduce chances of the wearable device 100 from being downwardly separated due to gravity while the user is wearing the wearable device 100. The base body 80 may distribute a portion of the weight of the wearable device 100 to the waist of the user while the user is wearing the wearable device 100. The base body 80 may be connected to the waist support frame 20. Waist support frame connecting elements (not illustrated) for connecting to the waist support frame 20 may be provided at both ends of the base body 80.

In an embodiment, the lighting unit 85 may be disposed on an outer surface of the base body 80. The lighting unit 85 may include a light source (e.g., a light-emitting diode (LED)). The lighting unit 85 may emit light under control of a processor (not illustrated) (e.g., a processor 512 of FIGS. 5A and 5B) of the wearable device 100. Depending on the embodiment, the lighting unit 85 may be controlled to provide (or output) visual feedback corresponding to a state of the wearable device 100 via the lighting unit 85.

In an embodiment, a display (not illustrated) may be provided on the outer surface of the base body 80. The display may provide a screen for a variety of visual information (e.g., state information of the wearable device 100) related to the wearable device 100 and a UI.

The waist support frame 20 may support the body (e.g., the waist) of the user when the wearable device 100 is worn on the body of the user. The waist support frame 20 may extend from both ends of the base body 80. The lumbar region of the user may be accommodated inside the waist support frame 20. The waist support frame 20 may include at least one rigid body beam. Each beam may have a curved shape having a preset curvature to enclose the lumbar region of the user. A waist fastening portion 60 may be connected, directly or indirectly, to an end portion of the waist support frame 20. The driving modules 35 and 45 may be directly or indirectly connected to the waist support frame 20.

In an embodiment, a processor, a memory (e.g., a memory 514 of FIGS. 5A and 5B), an IMU (e.g., the IMU 135 of FIG. 1 or an IMU 522 of FIG. 5B), a communication module (e.g., a communication module 516 of FIGS. 5A and 5B), a sound output module (e.g., the sound output module 550 of FIGS. 5A and 5B), and a battery (not illustrated). The base body 80 may protect components disposed therein. The processor may generate a control signal for controlling an operation of the wearable device 100. The processor may control motors (or actuators) of the driving modules 35 and 45 that generate a torque based on electric energy stored in the battery. The processor and the memory may be included in control circuitry. The control circuitry may further include a power supply circuit to supply power from the battery to each component of the wearable device 100.

In an embodiment, the wearable device 100 may include a sensor module (not illustrated) (e.g., the sensor module 520 of FIG. 5A) that obtains sensor data from one or more sensors. The sensor module may obtain sensor data including motion information of the user and/or motion information of a component of the wearable device 100. The sensor module may include, for example, an IMU (e.g., the IMU 135 of FIG. 1 or the IMU 522 of FIG. 5B) to measure a motion value of the upper body of the user or a motion value of the waist support frame 20 and an angle sensor (e.g., the angle sensor 125 of FIG. 1, a first angle sensor 524 and a second angle sensor 524-1 of FIG. 5B) to measure an angle value of the hip joint of the user or a motion value of the torque transmission frame 50 or 55, but the example is not limited thereto. For example, the sensor module may further include at least one of a pressure sensor, a position sensor, a temperature sensor, a biosignal sensor, a distance sensor, or a proximity sensor.

The waist fastening portion 60 may be directly or indirectly connected to the waist support frame 20 and may fix the waist support frame 20 to the waist of the user. The waist fastening portion 60 may include, for example, a pair of belts.

The driving modules 35 and 45 may generate an external force (or a torque) applied to the body of the user based on a control signal generated by the processor. For example, the driving modules 35 and 45 may generate an assistance force or a resistance force applied to the legs of the user. In an embodiment, the driving modules 35 and 45 may include the first driving module 45 positioned corresponding to a position of the right hip joint of the user and the second driving module 35 positioned corresponding to a position of the left hip joint of the user. The first driving module 45 may include a first actuator and a first joint member, and the second driving module 35 may include a second actuator and a second joint member. The first actuator may provide power delivered to the first joint member, and the second actuator may provide power delivered to the second joint member. The first actuator and the second actuator may each include a motor that generates power (or a torque) by receiving electric power from the battery. When the motor is driven by receiving the electric power, the motor may generate a force (an assistance force) to assist a body motion of the user or a force (a resistance force) to hinder a body motion of the user. In an embodiment, the control module may adjust the magnitude and direction of the force generated by the motor by adjusting a voltage and/or a current supplied to the motor.

In an embodiment, the first joint member and the second joint member may respectively receive power from the first actuator and the second actuator and may apply an external force to the body of the user based on the received power. In an embodiment, the first joint member and the second joint member may be disposed at positions corresponding to joint portions of the user, respectively. One side of the first joint member may be directly or indirectly connected to the first actuator, and the other side may be directly or indirectly connected to the first torque transmission frame 55. The first joint member may be rotated by the power received from the first actuator. An encoder or a hall sensor that may function as an angle sensor to measure a rotation angle (corresponding to a joint angle of the user) of the first joint member or the first torque transmission frame 55 may be disposed on the one side of the first joint member. One side of the second joint member may be connected, directly or indirectly, to the second actuator, and the other side may be connected to the second torque transmission frame 50. The second joint member may be rotated by the power received from the second actuator. An encoder or a hall sensor that may function as an angle sensor to measure a rotation angle of the second joint member or the second torque transmission frame 50 may also be disposed on one side of the second joint member.

In an embodiment, the first actuator may be disposed in a lateral direction of the first joint member, and the second actuator may be disposed in a lateral direction of the second joint member. A rotation axis of the first actuator and a rotation axis of the first joint member may be spaced apart from each other, and a rotation axis of the second actuator and a rotation axis of the second joint member may also be spaced apart from each other. However, the example is not limited thereto, and the actuator and the joint member may share the rotation axis. In an embodiment, each actuator may be spaced apart from the joint member. In this case, the driving modules 35 and 45 may further include a power transmission module (not illustrated) to transmit power from the actuator to the joint member. The power transmission module may be a rotary body, such as a gear, or a longitudinal member, such as a wire, a cable, a string, a spring, a belt, or a chain. However, the scope of the embodiment is not limited to the positional relationship between the actuator and the joint member and the power transmission structure.

In an embodiment, when the wearable device 100 is worn on the legs of the user, the first torque transmission frame 55 and the second torque transmission frame 50 may transmit the torque generated by the first driving module 45 and the second driving module 35 to the body (e.g., the legs) of the user, respectively. The transmitted torque may act as an external force applied to a leg motion of the user. End portions of the first torque transmission frame 55 and the second torque transmission frame 50 may be directly or indirectly connected to the joint members and may be rotated. As the other end portions of the first torque transmission frame 55 and the second torque transmission frame 50 are directly or indirectly connected to the first thigh fastening portion 2 and the second thigh fastening portion 1, respectively, the first torque transmission frame 55 and the second torque transmission frame 50 may transmit the torque generated by the first driving module 45 and the second driving module 35 while supporting the thighs of the user. For example, the first torque transmission frame 55 and the second torque transmission frame 50 may push or pull the thighs of the user. The first torque transmission frame 55 and the second torque transmission frame 50 may each extend in a longitudinal direction of the thigh of the user and be bent to surround at least a portion of the circumference of the thigh of the user. The first torque transmission frame 55 may be a torque transmission frame to transmit a torque to the right leg of the user, and the second torque transmission frame 50 may be a torque transmission frame to transmit a torque to the left leg of the user.

The first thigh fastening portion 2 and the second thigh fastening portion 1 may be directly or indirectly connected to the first torque transmission frame 55 and the second torque transmission frame 50 and may fix the wearable device 100 to the legs (specifically, thighs) of the user. The first thigh fastening portion 2 may be a thigh fastening portion to fix the wearable device 100 to the right thigh of the user, and the second thigh fastening portion 1 may be a thigh fastening portion to fix the wearable device 100 to the left thigh of the user.

In an embodiment, the first thigh fastening portion 2 may include a first cover, a first fastening frame, and a first strap, and the second thigh fastening portion 1 may include a second cover, a second fastening frame, and a second strap. The first cover and the second cover may apply the torques generated by the first driving module 45 and the second driving module 35 to the thighs of the user, respectively. The first cover and the second cover may be disposed on one sides of the thighs of the user to push or pull the thighs of the user. The first cover and the second cover may be arranged in the circumferential directions of the thighs of the user. The first cover and the second cover may extend to both ends based on the other end portions of the first torque transmission frame 55 and the second torque transmission frame 50, respectively, and may include curved surfaces corresponding to the thighs of the user. End portions of the first cover and the second cover may be directly or indirectly connected to the first fastening frame and the second fastening frame, respectively. The other end portions of the first cover and the second cover may be directly or indirectly connected to the first strap and the second strap, respectively.

The first fastening frame and the second fastening frame may be disposed, for example, to surround at least some portions of the circumferences of the thighs of the user, thereby reducing the possibility or preventing the thighs of the user from being separated from the wearable device 100. The first fastening frame may have a fastening structure that connects the first cover to the first strap, and the second fastening frame may have a fastening structure that connects the second cover to the second strap.

The first strap may surround a remaining portion of the circumference of the right thigh of the user that is not covered by the first cover and the first fastening frame, and the second strap may surround a remaining portion of the circumference of the left thigh of the user that is not covered by the second cover and the second fastening frame. The first strap and the second strap may include, for example, an elastic material (e.g., a band).

FIGS. 5A and 5B are diagrams illustrating configurations of a wearable device according to an embodiment.

Referring to FIG. 5, the wearable device 100 may include the control module 510 (including control circuitry such as processing circuitry), the communication module 516 including communication circuitry, the sensor module 520 including at least one sensor, a driving module 530, an input module 540 including circuitry, and the sound output module 550 including a speaker. The driving module 530 may include a motor 534 configured to generate power (e.g., torque) and a motor driver circuit 532 to drive the motor 534. The embodiment of FIG. 5A illustrates the driving module 530 including one motor driver circuit 532 and one motor 534, but this is an example. Referring to FIG. 5B, in a control system 500-1, a plurality (e.g., two or more) of motor driver circuits 532 and 532-1 and motors 534 and 534-1 may be provided. The driving module 530 including the motor driver circuit 532 and the motor 534 may correspond to the first driving module 45 of FIG. 3, and the driving module 530-1 including the motor driver circuit 532-1 and the motor 534-1 may correspond to the second driving module 35 of FIG. 3. The descriptions of the motor driver circuit 532 and the motor 534 described below may be applied to the motor driver circuit 532-1 and the motor 534-1 illustrated in FIG. 5B, respectively.

The sensor module 520 may include at least one sensor that obtains sensor data. The sensor module 520 may transmit the obtained sensor data to the control module 510. The sensor module 520 may include the IMU 522, the first angle sensor 524, and the second angle sensor 524-1 as illustrated in FIG. 5B. The IMU 522 may measure a motion value of the upper body of the user. For example, the IMU 522 may sense acceleration of the X, Y, and Z-axes and angular velocity of the X, Y, and Z-axes according to the motion of the user. The motion value of the upper body of the user may correspond to a motion value of a waist support frame of an exercise assistance device. The first angle sensor 524 and the second angle sensor 524-1 may measure a hip joint angle according to a leg motion of the user. The first angle sensor 524 may sense a hip joint angle of the right leg of the user, and the second angle sensor 524-1 may sense a hip joint angle of the left leg of the user. The first angle sensor 524 and the second angle sensor 524-1 may each include, for example, an encoder and/or a hall sensor. The hip joint angle of the right leg sensed by the first angle sensor 524 may correspond to a motion value (e.g., a rotation angle value) of the first torque transmission frame 55 of the wearable device 100, and the hip joint angle of the left leg sensed by the second angle sensor 524-1 may correspond to a motion value (e.g., a rotation angle value) of the second torque transmission frame 50 of the wearable device 100. In an embodiment, the sensor module 520 may further include a pressure sensor for measuring a pressure value, a position sensor for obtaining a position value of the wearable device 100, a proximity sensor for sensing the proximity of an object, a biosignal sensor for sensing a biosignal of the user, and/or a temperature sensor for measuring an ambient temperature.

Referring back to FIG. 5A, the input module 540 may receive, from the outside (e.g., the user) of the wearable device 100, an instruction or data to be used by a component (e.g., the processor 512) of the wearable device 100. The input module 540 may include, for example, a key (e.g., a button) and/or a touch screen.

The sound output module 550 may output a sound signal to the outside of the wearable device 100. The sound output module 550 may include a speaker configured to play a guide sound signal (e.g., a driving start sound or an operation error notification sound), music content, or a guiding voice.

In an embodiment, a control system 500 and/or the control system 500-1 may include a battery management system (not illustrated) for supplying power from a battery to each component of the wearable device 100 and controlling power supply. The battery management system may have, for example, a structure of a plurality of battery modules operated by a single batter management circuit. The battery management system is further described below.

The driving module 530 may generate an external force applied to the legs of the user under the control of the control module 510. The driving module 530 may be disposed at a position corresponding to a hip joint position of the user and may generate a torque applied to the leg of the user based on a control signal generated by the control module 510. The control module 510 may transmit the control signal to the motor driver circuit 532, and the motor driver circuit 532 may control the operation of the motor 534 by generating and providing a current signal (or a voltage signal) corresponding to the control signal to the motor 534. According to the control signal, the current signal may not be provided to the motor 534. The motor 534 may generate an assistance force that assists a leg motion of the user or a resistance force that hinders the leg motion when the motor 534 is driven as the current signal is provided to the motor 534.

The control module 510 may control the overall operation of the wearable device 100 and may generate a control signal to control each component of the wearable device 100. The control module 510 may include at least one processor 512 and the memory 514.

The processor 512 may execute, for example, software to control at least one of other components (e.g., hardware or software components) of the wearable device 100 directly or indirectly connected to the processor 512 and may perform various data processing or computations. According to an embodiment, as at least a part of data processing or computations, the processor 512 may store instructions or data received from the other component (e.g., the communication module 516) in the memory 514, may process the instructions or data stored in the memory 514, and may store resulting data of processing in the memory 514. The processor 512 may include one or more processors, and the operations of the processor 512 described herein may be performed by the one or more processors. According to an embodiment, the processor 512 may include at least one of a main processor (e.g., a central processing unit (CPU) or an application processor (AP)) or an auxiliary processor (e.g., a graphics processing unit (GPU), a neural processing unit (NPU), an image signal processor (ISP), a sensor hub processor, or a communication processor (CP)) that is operable independently from, or in conjunction with the main processor. The auxiliary processor may be implemented separately from the main processor or as a part of the main processor.

The memory 514 may store a variety of data used by at least one component (e.g., the processor 512) of the control module 510. The data may include, for example, software, sensor data, and input data or output data on instructions related thereto. The memory 514 may include volatile memory or non-volatile memory.

The communication module 516 may support establishment of a direct (e.g., wired) communication channel or a wireless communication channel between the control module 510 and the other component of the wearable device 100 or an external electronic device (e.g., the electronic device 210 or the other wearable device 220 of FIG. 2) and communication via the established communication channel. For example, the communication module 516 may transmit sensor data obtained by the sensor module 520 to an external electronic device (e.g., the electronic device 210 of FIG. 2) and may receive a control signal from the electronic device. According to an embodiment, the communication module 516 may include one or more CPs that are operated independently of the processor 512 and support direct (e.g., wired) communication or wireless communication. According to an embodiment, the communication module 516 may include a wireless communication module (e.g., a cellular communication module, a short-range wireless communication module, or a global navigation satellite system (GNSS) communication module), and/or a wired communication module. The wireless communication module may communicate with the other component of the wearable device 100 and/or an external device via, for example, Wi-Fi, advanced and adaptive network technology (ANT), infrared data association (IrDA), a legacy cellular network, a fifth generation (5G) network, a next-generation communication network, the Internet, or a computer network (e.g., a local area network (LAN) or a wide area network (WAN)).

The haptic module 560 may provide haptic feedback to the user under the control of the processor 512. The haptic module 560 may include one or a plurality of haptic actuators. The haptic actuator may include, for example, a piezo actuator, a bander type actuator, and/or a vibration motor-based actuator. One or a plurality of haptic actuators may be provided.

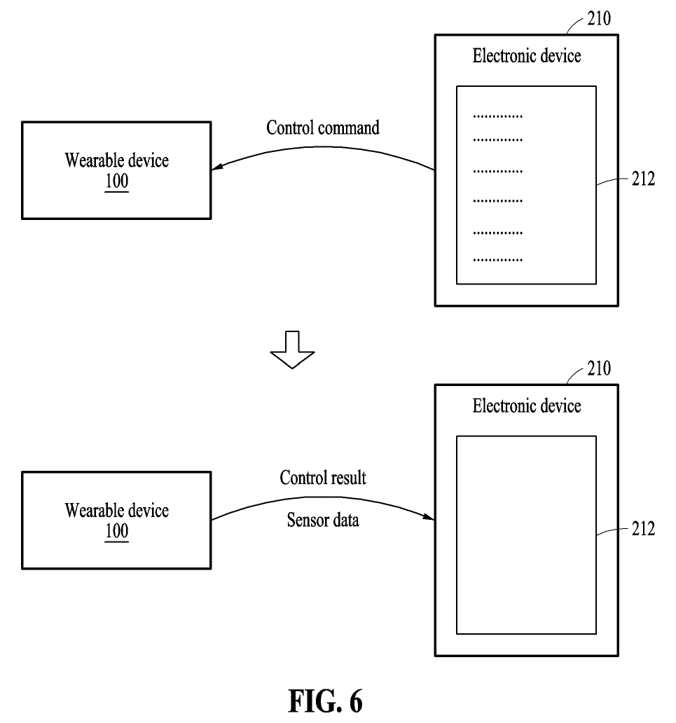

FIG. 6 is a diagram illustrating an interaction between a wearable device and an electronic device according to an embodiment.

Referring to FIG. 6, the wearable device 100 may communicate with the electronic device 210. For example, the electronic device 210 may be a user terminal of a user of the wearable device 100. According to an embodiment, the wearable device 100 and the electronic device 210 may be connected to each other via short-range wireless communication (e.g., Bluetooth^{TM} or Wi-Fi communication).

In an embodiment, the electronic device 210 may execute an application for identifying a state of the wearable device 100 or controlling or operating the wearable device 100. A screen of a UI may be displayed to control an operation of the wearable device 100 or determine an operation mode of the wearable device 100 on a display 212 of the electronic device 210 through the execution of the application. The UI may be, for example, a GUI.

In an embodiment, the user may input an instruction (e.g., an instruction to execute a walking assistance mode or an exercise assistance mode) to control the operation of the wearable device 100 or change settings of the wearable device 100 via a GUI screen on the display 212 of the electronic device 210. The electronic device 210 may generate a control instruction (or control signal) corresponding to an operation control instruction or a setting change instruction input by the user and may transmit the generated control instruction to the wearable device 100. The wearable device 100 may operate in response to the received control instruction and may transmit, to the electronic device 210, a control result in response to the control instruction and/or sensor data measured by the sensor module of the wearable device 100. The electronic device 210 may provide, on the GUI screen, the user with result information (e.g., current exercise state information, exercise result information, exercise posture evaluation information, or physical ability evaluation information) derived by analyzing the control result and/or the sensor data.

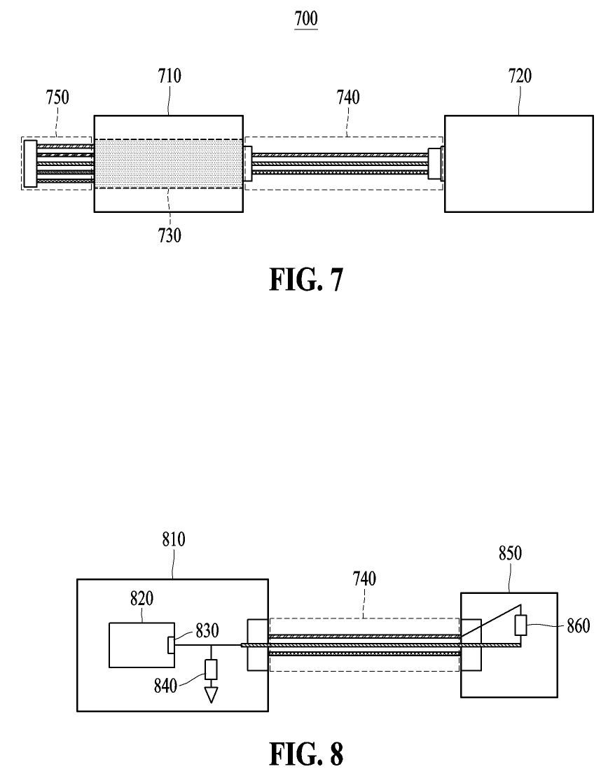

FIG. 7 is a diagram illustrating a configuration of a battery management system according to an embodiment.

Referring to FIG. 7, a battery management system 700 according to an embodiment may be included in a wearable device (e.g., the wearable device 100 of FIG. 1) that assists an exercise of a user and may supply power to at least one component of the wearable device. The battery management system 700 may be included in a battery pack, which is an integrated battery system.

The battery management system 700 may include a first battery cell 710, a second battery cell 720, a battery management circuit 730, and a cable 740 for connecting the first battery cell 710 to the second battery cell 720. The battery management system 700 may further include a port 750 to output information (e.g., a battery voltage, a current, a temperature, or the amount of electric charges) related to the battery and/or power of the first battery cell 710 and the second battery cell 720 or receiving a control instruction (e.g., an instruction to request to report a battery state or an instruction to control a fuse) transmitted to the battery management circuit 730. In addition, the battery management system 700 may further include a protective circuit (not illustrated) to protect a battery and/or a cooling circuit (not illustrated) to cool the battery. In an embodiment, the battery management system 700 may include a main module including the first battery cell 710 and the battery management circuit 730, and a sub-module that does not include a separate battery management circuit but includes the second battery cell 720 and a battery cell circuit (e.g., a battery cell circuit 850 of FIG. 8) of the second battery cell 720.

For ease of description, in the present disclosure, the battery management system 700 having a structure in which the first battery cell 710 and the second battery cell 720 are connected in series by the cable 740, is described as an embodiment. However, it shall not be understood that the scope of the embodiment is limited thereto. The battery management system 700 may include three or more battery cells, and the battery cells included in the battery management system 700 may be connected in parallel. In addition, some of the battery cells included in the battery management system 700 may be connected in series and the other batteries may be connected in parallel. In addition, the first battery cell 710 and the second battery cell 720 may each be replaced with a battery module that is a set of multiple battery cells.

The first battery cell 710 and the second battery cell 720 may each be a secondary battery that is used by charging or discharging electric energy. For example, the first battery cell 710 and the second battery cell 720 may be lithium-ion (Li-ion) batteries. The first battery cell 710 and the second battery cell 720 may be used as a power source of the wearable device 100. The first battery cell 710 and the second battery cell 720 may each include, for example, a positive electrode current collector, a negative electrode current collector, a separator, liquid electrolytes, and a thin film layer. The first battery cell 710 and the second battery cell 720 may be separated or connected by a cable 740. At both ends of the cable 740, connectors may be provided to connect to the first battery cell 710 and the second battery cell 720.

The battery management circuit 730 may monitor states of the first battery cell 710 and the second battery cell 720 and may perform a control or management operation for the battery management system 700. The battery management circuit 730 may monitor respective voltages (or currents, temperatures) of the first battery cell 710 and the second battery cell 720. For example, the battery management circuit 730 may periodically measure voltages (or currents, temperatures) of the first battery cell 710 and the second battery cell 720 and may determine states of the first battery cell 710 and the second battery cell 720 based on the measured values. When an abnormal situation is determined to have occurred in the first battery cell 710 and/or the second battery cell 720, the battery management circuit 730 may protect the first battery cell 710 and the second battery cell 720 by performing control according to the abnormal situation. For example, when an abnormal situation, such as overvoltage, overcurrent, or overcharging, occurs in the first battery cell 710 and/or the second battery cell 720, the battery management circuit 730 may perform a management operation to stop driving the battery management system 700.

In an embodiment, based on whether the first battery cell 710 and the second battery cell 720 are separated and whether the first battery cell 710 and the second battery cell 720 are connected by the cable 740, the battery management circuit 730 may identify whether a failure in the first battery cell 710 and/or the second battery cell 720 occurs or the first battery cell 710 and the second battery cell 720 are arbitrarily separated.

In an embodiment, based on respective voltages of the first battery cell 710 and the second battery cell 720 and whether the first battery cell 710 and the second battery cell 720 are connected via the cable 740, the battery management circuit 730 may determine whether to switch the states of the first battery cell 710 and the second battery cell 720 to a permanent fail state (or permanently unusable state).

In an embodiment, the battery management circuit 730 may detect separation between the first battery cell 710 and the second battery cell 720 based on the respective voltages of the first battery cell 710 and the second battery cell 720. When an abnormal voltage (e.g., 0 volt (V)) is detected in at least one of the first battery cell 710 and the second battery cell 720, the battery management circuit 730 may determine that the first battery cell 710 and the second battery cell 720 are separated from each other.

In an embodiment, when the first battery cell 710 and the second battery cell 720 are determined to be separated from each other, the battery management circuit 730 may examine whether the first battery cell 710 and the second battery cell 720 are connected by the cable 740. When the battery management circuit 730 detects that a low signal generated by a pull-down resistor (e.g., a pull-down resistor 840 of FIG. 8) included in the battery management system 730 is applied to an input terminal of a fuel gauge integrated circuit (IC) (e.g., a fuel gauge IC 820) included in the battery management circuit 730, the battery management circuit 730 may determine that the first battery cell 710 and the second battery cell 720 are not connected by the cable 740. When the battery management circuit 730 detects that a high signal generated by a pull-up resistor (e.g., a pull-up resistor 860 of FIG. 8) included in a battery cell circuit (e.g., the battery cell circuit 850 of FIG. 8) of the second battery cell 720 is applied to the input terminal of the fuel gauge IC, the battery management circuit 730 may determine that the first battery cell 710 and the second battery cell 720 are connected by the cable 740.

In an embodiment, when the battery management circuit 730 determines that the first battery cell 710 and the second battery cell 720 are separated from each other and the first battery cell 710 and the second battery cell 720 are connected by the cable 740, the battery management circuit 730 may switch the states of the first battery cell 710 and the second battery cell 720 to the permanent fail state. When the states are switched to the permanent fail state, the battery management circuit 730 may perform protective measures for safety. For example, the battery management circuit 730 may perform a control operation to disconnect a fuse circuit so that the power of the first battery cell 710 and/or the second battery cell 720 is not supplied to the outside. The first battery cell 710 and the second battery cell 720 that are switched to the permanent fail state may be switched to an unusable state.

In an embodiment, when the battery management circuit 730 determines that the first battery cell 710 and the second battery cell 720 are separated from each other and the first battery cell 710 and the second battery cell 720 are not connected by the cable 740, the battery management circuit 730 may switch the states of the first battery cell 710 and the second battery cell 720 to a standby state without switching the states of the first battery cell 710 and the second battery cell 720 to the permanent fail state. When the battery management circuit 730 detects that the first battery cell 710 and the second battery cell 720 in the standby states are connected by the cable 740, the battery management circuit 730 may switch the states of the first battery cell 710 and the second battery cell 720 to a normal operation state. When non-connection of the cable 740 is detected, the battery management circuit 730 may switch the states of first battery cell 710 and the second battery cell 720 to the standby state, and then when the high signal generated by the pull-up resistor of the battery cell circuit of the second battery cell 720 is applied to the input terminal of the fuel gauge IC, the battery management circuit 730 may detect that the first battery cell 710 and the second battery cell 720 are re-connected by the cable 740. When the reconnection of the cable 740 is detected, the battery management circuit 730 may switch the states of the first battery cell 710 and the second battery cell 720 to the normal operation state.

In a conventional battery system, a battery pack including a plurality of battery cells is configured as an integrated body, and when the user arbitrarily separates a battery cell, a voltage of the separated battery cell is recognized as 0V, and the battery pack is switched to the permanent fail state. The battery back switched to the permanent fail state due to the separation of battery cell is no longer usable and is needed to be replaced with another battery pack. However, in the battery management system 700 proposed in the present disclosure, the battery cells 710 and 720 may be connected by the cable 740, and a case where a battery cell is arbitrarily separated (e.g., separated due to non-connection of the cable) from the battery pack structure may be distinguished from a case where an actual problem occurs (e.g., when an abnormal voltage is detected while the battery cells are connected by the cable) in the battery cell to determine whether to switch the battery cells to the permanent fail state. Even when the battery cells 710 and 720 are arbitrarily separated, the battery management system 700 may not immediately switch the battery pack to the permanent fail state, and when the separation of the battery cell due to non-connection of the cable 740 is detected, the battery pack may be switched to the standby state, and when the cable 740 is re-connected, the battery management system 700 may switch the battery cells 710 and 720 to a state in which a normal operation is available. By the control operation of the battery management system 700 described above, the battery cells 710 and 720 included in the battery pack may be separated and re-connected, and the battery pack may be prevented from, or chances reduced of, being unnecessarily switched to the permanent fail state. Since the separation and re-connection of the battery cells 710 and 720 are allowed, product design that separates and disposes the battery cells 710 and 720 at different positions may be allowed in a product to which the battery management system 700 is applied, and this may improve design convenience and assembly convenience of the product. In addition, the battery management system 700 may enable normal operation of the battery pack even when the battery cell is separated and re-connected for necessity or convenience of repair in a repair process of the product.

FIG. 8 is a diagram illustrating a battery management circuit and a battery cell circuit according to an embodiment.

Referring to FIG. 8, a battery management circuit 810 (e.g., the battery management circuit 730 of FIG. 7) and the battery cell circuit 850 are illustrated. The battery management circuit 810 may include the fuel gauge IC 820 that determines whether a first battery cell (e.g., the first battery cell 710 of FIG. 7) and a second battery cell (e.g., the second battery cell 720 of FIG. 7) are connected via the cable 740, and the pull-down resistor 840 connected to a reference voltage terminal and an input terminal of the fuel gauge IC 820. The battery management circuit 810 may further include a fuse circuit (not illustrated) that controls power supply from the first battery cell and the second battery cell. The fuse circuit may be provided in a charge/discharge path of the battery cell.

In an embodiment, the fuel gauge IC 820 may sense voltage, currents, and/or temperatures of the first battery cell and the second battery cell and may perform a function to block overcharging and overdischarging of the first battery cell and the second battery cell. The fuel gauge IC 820 may include one or more ports 830, and various signals may be input or output via the port 830. The port 830 may be, for example, a general purpose input output (GPIO) port.

In an embodiment, a first port of the cable 740 may be connected to the first battery cell and the battery management circuit 810, and a second port of the cable 740 may be connected to the second battery cell and the battery cell circuit 850 of the second battery cell. When the cable 740 is connected to the second battery cell, the battery cell circuit 850 of the second battery cell may include signal transmission lines connected to a plurality of signal lines included in the cable 740 and the pull-up resistor 860 connected between the signal transmission lines.

The fuel gauge IC 820 may detect whether the first battery cell and the second battery cell are separated and whether the first battery cell and the second battery cell are connected by the cable 740. When an abnormal voltage (e.g., 0V) that is significantly less than an expected voltage is detected in at least one of the first battery cell and the second battery cell, the fuel gauge IC 820 may determine that the first battery cell and the second battery cell are separated from each other. Hereinafter, a case where the first battery cell and the second battery cell are connected by the cable 740 and a case where the first battery cell and the second battery cell are not connected by the cable 740 and are separated from each other are separately described.

When the first battery cell and the second battery cell are connected by the cable 740

When the first battery cell and the second battery cell are connected by the cable 740, a high signal may be generated by the pull-up resistor 860 of the battery cell circuit 850. A power line voltage (e.g., 3.3 V or 1.8 V) (or a positive electrode voltage of the second battery cell) may be applied to an end of the pull-up resistor 860, and a signal generated by the applied power line voltage may have a relatively high signal level (e.g., a voltage level) than a signal generated by the pull-down resistor 840, thereby indicating a high signal. The high signal generated by the pull-up resistor 860 may be transmitted to the battery management circuit 810 via the cable 740, and the high signal may be input to the input terminal of the fuel gauge IC 820 in the battery management circuit 810. When the high signal generated by the pull-up resistor 860 and applied to the input terminal (included in the port 830) of the fuel gauge IC 820 is detected, the fuel gauge IC 820 may determine that the first battery cell and the second battery cell are connected by the cable 740.

When the first battery cell and the second battery cell are not connected by the cable 740 and are separated from each other

When the first battery cell and the second battery cell are not connected by the cable 740 and are separated from each other, a low signal may be generated by the pull-down resistor 840 of the battery management circuit 810. A ground (GND) voltage (e.g., 0V) (or a negative electrode voltage of the first battery cell) is applied to an end of the pull-down resistor 840, and a signal generated by the applied GND voltage may have a relatively low signal level (e.g., the voltage level) than a signal generated by the pull-up resistor 860, thereby indicating a low signal. The low signal generated by the pull-down resistor 840 may be transmitted to the fuel gauge IC 820, and when the fuel gauge IC 820 detects that the low signal generated by the pull-down resistor 840 is applied to the input terminal of the fuel gauge IC 820, the fuel gauge IC 820 may determine that the first battery cell and the second battery cell are not connected by the cable 740. In response to determining that the first battery cell and the second battery cell are not connected by the cable 740, the fuel gauge IC 820 may keep a state of the fuse circuit in a currently connected state. When an abnormal voltage is detected in at least one of the first battery cell and the second battery cell while the first battery cell and the second battery cell are determined to be connected by the cable 740, the fuel gauge IC 820 may perform a control operation to disconnect the fuse circuit.

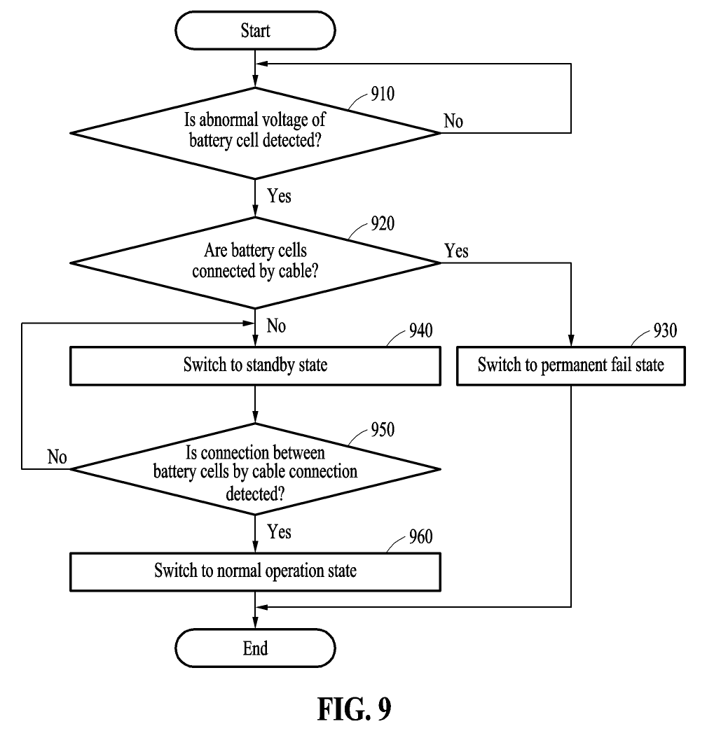

FIG. 9 is a flowchart of operations of a control method of a battery management system according to an embodiment.

FIG. 9 is a flowchart of operations of a control method of a battery management system (e.g., the battery management system 700 of FIG. 7) according to an embodiment. In an embodiment, at least one of the operations of FIG. 9 may be performed simultaneously or in parallel with other operations, and the order of operations may be changed. In addition, at least one of the operations may be omitted, and other operations may be additionally performed.

Referring to FIG. 9, a battery management circuit (e.g., the battery management circuit 730 of FIG. 7 and the battery management circuit 810 of FIG. 8) of the battery management system may monitor respective voltages of battery cells (e.g., the first battery cell 710 and the second battery cell 720 of FIG. 7). In operation 910, the battery management circuit may determine whether an abnormal voltage of at least one of the battery cells is detected.

When the abnormal voltage of at least one of the battery cells is determined to be detected (when "yes" is determined in operation 910), in operation 920, the battery management circuit may determine whether the battery cells are connected via a cable (e.g., the cable 740 of FIG. 7). In an embodiment, when a low signal generated by a pull-down resistor (e.g., the pull-down resistor 840 of FIG. 8) included in the battery management circuit is detected, the battery management circuit may determine that the battery cells are not connected by the cable. When a high signal generated by a pull-up resistor (e.g., the pull-up resistor 860 of FIG. 8) included in the battery cell circuit (e.g., the battery cell circuit 850 of FIG. 8) connected to the cable is detected, the battery management circuit may determine that the battery cells are connected by the cable.

When an abnormal voltage of at least one of the battery cells is detected and the battery cells are detected to be connected via the cable (in the case of "yes" in operation 920), the battery management circuit may switch states of the battery cells to the permanent fail state. When the states of the battery cells are switched to the permanent fail state, the battery management circuit may perform a control operation to disconnect a fuse circuit that controls power supply from the battery cells.

When the battery cells are detected to be unconnected by the cable (in the case of "no" in operation 920), in operation 940, the battery management circuit may switch the states of the battery cells to the standby state without switching the states of the battery cells to the permanent fail state. In operation 950, the battery management circuit may determine whether the connection between the battery cells by the cable is detected in the standby state. In the standby state, when the battery cells are detected to be connected by the cable (e.g., when "yes" is determined in operation 950), in operation 960, the battery management circuit may switch the states of the battery cells to the normal operation state. When a high signal generated by the battery cell circuit that is reconnected by the cable is detected, the battery management circuit may determine that the battery cells are reconnected by the cable.

When an abnormal voltage (e.g., 0V) is detected in at least one of the battery cells included in a battery pack, the battery management circuit may not immediately set the battery pack to the permanent fail state and may identify whether the abnormal voltage of the battery cell is detected because the battery cells are arbitrarily separated by the user's intention or is detected because of a failure (or anomaly) in the battery cell by detecting whether the cable is separated. When the abnormal voltage of the battery cell is detected due to the separation of the cable by the user, the battery management circuit may wait in the standby state without disconnecting the fuse circuit. Thereafter, when reconnection of the cable is detected, the battery management circuit may cause the battery pack including the battery cells to normally operate again.

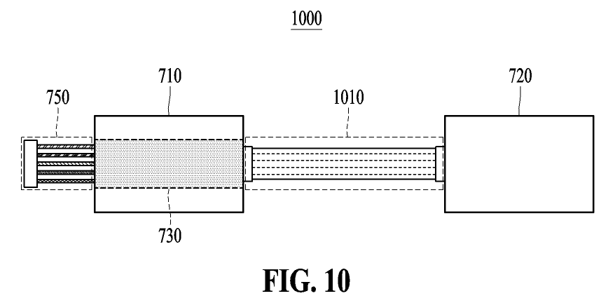

FIG. 10 is a diagram illustrating a battery management system including an FPCB according to an embodiment.

Referring to FIG. 10, a battery management system 1000 may include the first battery cell 710, the second battery cell 720, the battery management circuit 730, and an FPCB 1010 that connects the first battery cell 710 to the second battery cell 720. The connection between the first battery cell 710 and the second battery cell 720 may be enabled by not only the cable 740 illustrated in FIG. 7 but also an electronic component, such as the FPCB 1010. In addition to the FPCB 1010, any means capable of transmitting a signal between the first battery cell 710 and the second battery cell 720 may be applied without restriction.

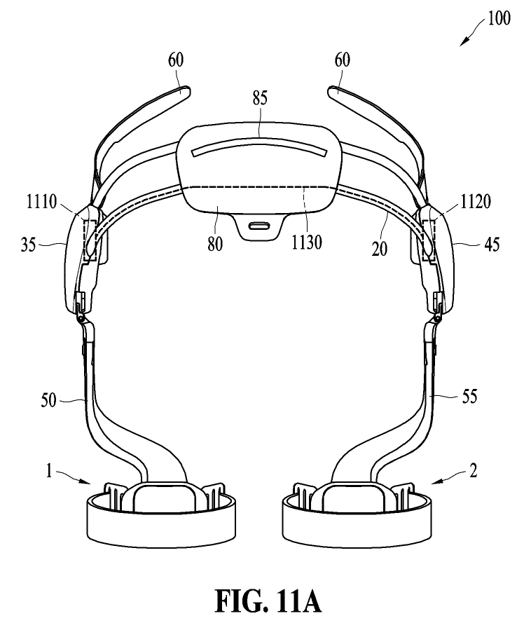

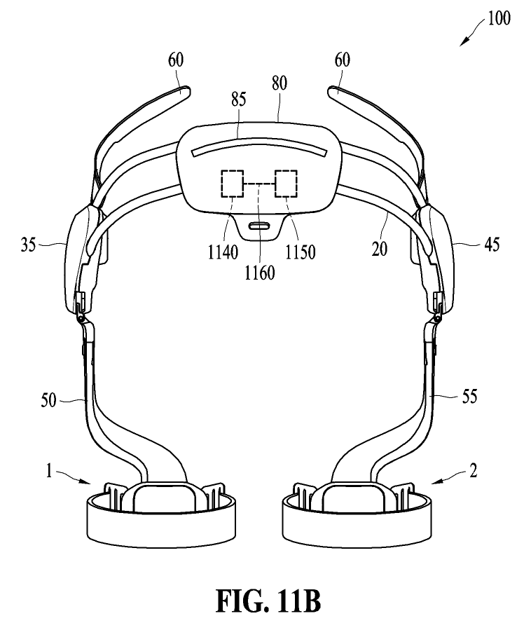

FIGS. 11A and 11B are diagrams illustrating implementation examples in which a battery management system is provided in a wearable device according to an embodiment.

Referring to FIG. 11A, in the wearable device 100 according to an embodiment, a main module 1120 including a first battery cell (e.g., the first battery cell 710 of FIG. 7) and a battery management circuit (e.g., the battery management circuit 730 of FIG. 7) may be disposed adjacent to the first driving module 45, and a sub-module 1110 including a second battery cell (e.g., the second battery cell 720 of FIG. 7) and a battery cell circuit (e.g., the battery cell circuit 850 of FIG. 8) of the second battery cell may be disposed adjacent to the second driving module 35. The main module 1120 and the sub-module may supply power required by each component of the wearable device 100. Depending on the embodiment, the main module 1120 may be disposed adjacent to the second driving module 35, and the sub-module 1110 may be disposed adjacent to the first driving module 45.

The main module 1120 and the sub-module 1110 may be connected to each other via a cable 1130 (e.g., the cable 740 of FIG. 7). In an embodiment, the cable 1130 may be disposed along an internal path of the waist support frame 20 to connect the main module 1120 to the sub-module 1110. In the case of a battery pack including multiple battery cells, since a weight felt by a user wearing the wearable device 100 may be heavy, a weight of the battery pack may be distributed when the battery cells are separately disposed on both sides, such as the main module 1120 and the sub-module 1110 as illustrated. To separately dispose the battery cells on both sides, the connection of the cable 1130 between the main module 1120 and the sub-module 1110 may need to be temporarily disconnected in an assembly process of the wearable device 100. Even when the connection of the cable 1130 between the main module 1120 and the sub-module 1110 is disconnected, the battery management circuit may determine whether the connection of the cable 1130 is disconnected without immediately switching the battery cells to the permanent fail state. When the connection of the cable 1130 is determined to be disconnected, the battery management circuit may wait in the standby state, and when the connection of the cable 1130 is detected, the battery management circuit may cause the battery pack including the battery cells to resume the normal operation.

Referring to FIG. 11B, in the wearable device 100 according to an embodiment, a main module 1140 including a first battery cell (e.g., the first battery cell 710 of FIG. 7) and a battery management circuit (e.g., the battery management circuit 730 of FIG. 7), a sub-module 1150 including a second battery cell (e.g., the second battery cell 720 of FIG. 7) and a battery cell circuit (e.g., the battery cell circuit 850 of FIG. 8) of the second battery cell, and a cable 1160 (e.g., the cable 740 of FIG. 7) connecting the main module 1140 to the sub-module 1150 may be disposed in the base body 80. In the base body 80, the main module 1140 and the sub-module 1150 may be disposed apart from each other on both sides.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, "A or B", "at least one of A and B", "at least one of A or B", "A, B or C", "at least one of A, B and C", and "at least one of A, B, or C," each of which may include any one of the items listed together in the corresponding one of the phrases, or all possible combinations thereof. As used herein, such terms as "1st" and "2nd," or "first" and "second" may be used to simply distinguish a corresponding component from another, and does not limit the components in other aspect (e.g., importance or order). It is to be understood that if an element (e.g., a first element) is referred to, with or without the term "operatively" or "communicatively", as "coupled with," "coupled to," "connected with," or "connected to" another element (e.g., a second element), it means that the element may be coupled with the other element directly (e.g., wiredly), wirelessly, or via at least a third element.

As used in connection with embodiments of the disclosure, the term "module" may include a unit implemented in hardware, software, or firmware, and may interchangeably be used with other terms, for example, "logic," "logic block," "part," or "circuitry." A module may be a single integral component, or a minimum unit or part thereof, adapted to perform one or more functions. For example, according to an embodiment, the module may be implemented in a form of an application-specific integrated circuit (ASIC). Accordingly, each "module" herein may include a circuit.

The software may include a computer program, a piece of code, an instruction, or some combination thereof, to independently or uniformly instruct or configure the processing device to operate as desired. Software and data may be embodied permanently or temporarily in any type of machine, component, physical or virtual equipment, or computer storage medium or device capable of providing instructions or data to or being interpreted by the processing device. The software also may be distributed over network-coupled computer systems so that the software is stored and executed in a distributed fashion. The software and data may be stored by one or more non-transitory computer-readable recording mediums. Embodiments as set forth herein may be implemented as software including one or more instructions that are stored in a storage medium that is readable by a machine. For example, a processor of the machine may invoke at least one of the one or more instructions stored in the storage medium and execute it. This allows the machine to be operated to perform at least one function according to the at least one instruction invoked. The one or more instructions may include code generated by a compiler or code executable by an interpreter. The machine-readable storage medium may be provided in the form of a non-transitory storage medium. Wherein, the term "non-transitory" simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to the embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smartphones) directly. If distributed online, at least part of the computer program product may be temporarily generated or at least temporarily stored in the machine-readable storage medium, such as memory of the manufacturer's server, a server of the application store, or a relay server.

According to embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

Although the present disclosure exemplifies and describes with reference to various embodiments, it shall be construed that various embodiments are for the illustrative purpose rather than limiting. It shall be further understood by those skilled in the art that various changes in forms and details may be made without departing from the true spirit and full scope of this disclosure including the scope of the attached claims and their equivalents. In addition, it shall be construed that the embodiments described herein may be used with other embodiments of the present disclosure.

1. A battery management system comprising:
a first battery cell;
a second battery cell;
a cable configured for connecting the first battery cell and the second battery cell; and
a battery management circuit configured to monitor respective voltages of the first battery cell and the second battery cell and determine whether to switch states of the first battery cell and the second battery cell to a permanent fail state, based on the respective voltages of the first battery cell and the second battery cell and whether the first battery cell and the second battery cell are connected via the cable.

2. The battery management system of claim 1,
wherein the battery management circuit is configured to:
other when an abnormal voltage is detected in at least one of the first battery cell and the second battery cell, determine that the first battery cell and the second battery cell are separated from each other, and
when the first battery cell and the second battery cell are determined to be separated from each other, examine whether the first battery cell and the second battery cell are connected via the cable.

3. The battery management system of claim 2,
wherein the battery management circuit is configured to:
when the first battery cell and the second battery cell are determined to be separated from each other and the first battery cell and the second battery cell are determined to be connected by the cable, switch the states of the first battery cell and the second battery cell to the permanent fail state.

4. The battery management system of claim 2,
wherein the battery management circuit is configured to:
when the first battery cell and the second battery cell are determined to be separated from each other and the first battery cell and the second battery cell are determined not to be connected via the cable, switch the states of the first battery cell and the second battery cell to a standby state without switching to the permanent fail state.

5. The battery management system of claim 4,
wherein the battery management circuit is configured to:
when the first battery cell and the second battery cell are determined to be connected by the cable in the standby state, switch the states of the first battery cell and the second battery cell to a normal operation state.

6. The battery management system of claim 1,
wherein the battery management circuit comprises:
a fuel gauge integrated circuit configured to determine whether the first battery cell and the second battery cell are connected via the cable;
a pull-down resistor connected between at least a reference voltage terminal and an input terminal of the fuel gauge integrated circuit; and
a fuse circuit configured to control power supply from the first battery cell and the second battery cell.

7. The battery management system of claim 6,
wherein the fuel gauge integrated circuit is configured to:
when the a low signal generated by the pull-down resistor and applied to the input terminal of the fuel gauge integrated circuit is detected, determine that the first battery cell and the second battery cell are not connected via the cable.

8. The battery management system of claim 7,
wherein the fuel gauge integrated circuit is configured to:
in response to determining that the first battery cell and the second battery cell are connected via the cable, keep a connection state of the fuse circuit in a currently connected state.

9. The battery management system of claim 7,
wherein the fuel gauge integrated circuit is configured to:
when an abnormal voltage is detected in at least one of the first battery cell and the second battery cell while the first battery cell and the second battery cell are determined to be connected, perform a control operation to disconnect the fuse circuit.

10. The battery management system of claim 6,
wherein a first port of the cable is connected to the first battery cell and the battery management circuit,
a second port of the cable is connected to the second battery cell and a battery management circuit of the second battery cell.

11. The battery management system of claim 10,
wherein the battery cell circuit of the second battery cell comprises:
signal transmission lines connected to a plurality of signal lines comprised in the cable, when the cable is connected to the second battery cell; and
a pull-up resistor connected between the signal transmission lines.

12. The battery management system of claim 11,
wherein the fuel gauge integrated circuit is configured to:
when a high signal generated by the pull-up resistor and applied to the input terminal of the fuel gauge integrated circuit is detected, determine that the first battery cell and the second battery cell are connected.

13. The battery management system of claim 1,
wherein the first battery cell and the second battery cell are separated or are connected by the cable.

14. The battery management system of claim 1,
wherein the battery management system is included in a wearable device that assists an exercise of a user and supplies power to at least one component of the wearable device.

15. A method of controlling a battery management system comprising battery cells, a cable for connecting at least the battery cells, and a battery management circuit, the method comprising:
monitoring respective voltages of the battery cells;
when an abnormal voltage of at least one of the battery cells is detected, determining whether the battery cells are connected;
when the battery cells are detected not to be connected, switching states of the battery cells to a standby state without switching to a permanent fail state; and
when the battery cells are detected to be connected in the standby state, switching the states of the battery cells to a normal operation state.

16. The method of claim 15, further comprising:
when the abnormal voltage of at least one of the battery cells is detected and the battery cells are detected to be connected via the cable, switching the states of the battery cells to the permanent fail state.

17. The method of claim 16, wherein the switching the states of the battery cells to the permanent fail state comprises:
performing a control operation to disconnect a fuse circuit that controls power supply from the battery cells.

18. The method of claim 15, wherein the determining whether the battery cells are connected comprises:
when a low signal generated by a pull-down resistor included in the battery management circuit is detected, determining that the battery cells are not connected via the cable

19. The method of claim 15, wherein the determining whether the battery cells are connected comprises:
when a high signal generated by a pull-up resistor included in the battery cell circuit connected to the cable is detected, determining that the battery cells are connected via the cable.

20. A non-transitory computer-readable storage medium storing instructions that, when executed by a processor, cause the processor to perform the method of claim 15.
